(19) United States
(12) Patent Application Publication
(10) Pub. No.: US 2025/0351616 A1
(43) Pub. Date: Nov. 13, 2025

(54) PHOTODETECTOR AND METHOD OF DISTINGUISHINGLY DETECTING PHOTONS OF DIFFERENT PHOTON ENERGIES USING SAME

(71) Applicant: THE ROYAL INSTITUTION FOR THE ADVANCEMENT OF LEARNING/MCGILL UNIVERSITY, Montréal (CA)

(72) Inventors: Songrui ZHAO, Brossard (CA); Milad FATHABADI, Montréal (CA)

(21) Appl. No.: 19/201,118

(22) Filed: May 7, 2025

(30) Foreign Application Priority Data
May 9, 2024 (CA) 3237978

(51) Int. Cl. H10F 77/14; H10F 30/222; H10F 77/00; H10F 77/124; H10F 77/50

(52) U.S. Cl. CPC H10F 77/1437; H10F 30/222; H10F 77/1246; H10F 77/50; H10F 77/953

(57) ABSTRACT

The photodetector device generally has a semiconductor substrate; a plurality of nanowires extending from the semiconductor substrate, the nanowires having a first section of a first semiconductor material extending from the semiconductor substrate, a tunnel junction extending from the first section, and a second section of a second semiconductor material extending from the tunnel junction, the first semiconductor material having a first bandgap energy different from a second bandgap energy of the second semiconductor material; an electrode longitudinally spaced apart from the second sections, and forming a gap therebetween; an electrolyte solution within the gap and surrounding the nanowires; and a current detector having a first terminal electrically connected to the semiconductor substrate and a second terminal electrically connected to the electrode.

### FIELD

The improvements relate to photodetectors and more specifically relate to heterojunction-based nanowire photodetectors that can distinguishingly detect photons of different wavelengths, frequencies or photon energies.

### BACKGROUND

A heterojunction-based nanowire device has an interface between two nanowire sections of dissimilar semiconductor materials. These semiconducting materials have unequal or different band gaps as opposed to a homojunction. It can be advantageous to engineer the electronic energy bands in many solid-state device applications, including semiconductor lasers, solar cells and transistors, to tune the functionalities of the resulting heterojunction-based nanowire devices. In at least some photodetector applications, such heterojunctions are made integral to semiconductor nanowires to detect incoming photons. Although existing heterojunction-based nanowire photodetectors are satisfactory to a certain degree, there remains room for improvement.

### SUMMARY

In some applications, it was found that heterojunction-based nanowire photodetectors could theoretically distinguishingly detect different photon energies. Indeed, a first section of the semiconductor nanowire can receive photons of a first photon energy, greater than a bandgap of the corresponding section of the semiconductor nanowire, and in turn generate a first photocurrent of a first polarity (or equivalently in a first direction). Similarly, a second section of the semiconductor nanowire can receive photons of a second photon energy, greater than bandgap of the corresponding section of the semiconductor nanowire, and in turn generate a second photocurrent of a second polarity (or equivalently in a second direction opposite). Theoretically, the first polarity is opposite to the second polarity (and the first direction is opposite to the second direction), which would be easily discernable at a current detector. However, there were challenges in discerning these opposite polarities, as negative photocurrent can quench due to built-in electric fields occurring at the heterojunction. In this disclosure, there is described a photodetector device in which tunnel junctions are made integral to the heterojunction of the nanowires, which can in turn reduce the adverse effect of having built-in electric field impeding the detectability of different photocurrent polarities.

In accordance with a first aspect of the present disclosure, there is provided a photodetector device comprising: a semiconductor substrate; a plurality of nanowires extending from the semiconductor substrate, the nanowires having a first section of a first semiconductor material extending from the semiconductor substrate, a tunnel junction extending from the first section, and a second section of a second semiconductor material extending from the tunnel junction, the first semiconductor material having a first bandgap energy different from a second bandgap energy of the second semiconductor material; an electrode longitudinally spaced apart from the second sections, and forming a gap therebetween; an electrolyte solution within the gap and surrounding the nanowires; and a current detector having a first terminal electrically connected to the semiconductor substrate and a second terminal electrically connected to the electrode.

Further in accordance with the first aspect of the present disclosure, the current detector can for example detect a first electrical current signal when first photons having a first photon energy exceeding the first bandgap energy impinge at least on the first sections, the current detector detecting a second electrical current signal when second photons having a second photon energy exceeding the second bandgap energy impinge at least on the second sections, the first electrical current signal having a first polarity different from a second polarity of the second electrical current signal.

Still further in accordance with the first aspect of the present disclosure, the photodetector device can for example further comprise a controller communicatively coupled to the current detector, the controller having a processor and a non-volatile computer memory having stored thereon instructions that when executed by the processor perform the steps of: at least one of: upon receiving a given electrical signal of the first polarity, generating a signal indicative that photons of the first photon energy have impinged on the nanowires, and upon receiving a given electrical signal of the second polarity, generating a signal indicative that photons of the second photon energy have impinged on the nanowires.

Still further in accordance with the first aspect of the present disclosure, the first semiconductor material can for example be an n-type doped semiconductor material, the second semiconductor material can for example be a p-type doped semiconductor material.

Still further in accordance with the first aspect of the present disclosure, the n-type doped semiconductor material can for example be an n-type doped gallium nitride (GaN), and the p-type doped semiconductor material can for example be a p-type doped indium gallium nitride (InGaN).

Still further in accordance with the first aspect of the present disclosure, the tunnel junction can for example have a third section of a third semiconductor material extending from the first section of the nanowire, a fourth section of a fourth semiconductor material extending from the third section, and a fifth section of a fifth semiconductor material extending between the fourth section and the second section of the nanowire.

Still further in accordance with the first aspect of the present disclosure, the third semiconductor material can for example be an n++-type doped semiconductor material, and the fifth semiconductor material can for example be a p++-type doped semiconductor material.

Still further in accordance with the first aspect of the present disclosure, the n++-type doped semiconductor material can for example be an n++-type doped GaN, and the p++-type doped semiconductor material can for example be p++-type doped GaN.

Still further in accordance with the first aspect of the present disclosure, the second semiconductor material and the fourth semiconductor material can for example be provided in the form of a similar semiconductor material.

Still further in accordance with the first aspect of the present disclosure, the similar semiconductor material can for example be indium gallium nitride (InGaN).

Still further in accordance with the first aspect of the present disclosure, the photodetector device can for example further comprise an enclosure enclosing the semiconductor substrate, the plurality of nanowires, the electrode and the electrolyte solution.

Still further in accordance with the first aspect of the present disclosure, the electrolyte solution can for example have a sodium chloride (NaCl) electrolyte.

Still further in accordance with the first aspect of the present disclosure, the electrolyte solution can for example include ions selected from the group comprising: K⁺, Mg²⁺, Ca²⁺, Br, SO₄², and CO₃²⁻.

Still further in accordance with the first aspect of the present disclosure, an underwater wireless sensor network can for example comprise one or more of the photodetector device.

In accordance with a second aspect of the present disclosure, there is provided a method of distinguishingly detecting photons of different bandgap energies using a photodetector device, the photodetector device having a semiconductor substrate, a plurality of nanowires extending from the semiconductor substrate, the nanowires having a first section of a first semiconductor material extending from the semiconductor substrate, and a second section of a second semiconductor material extending from the first section, the first semiconductor material having a first bandgap energy different from a second bandgap energy of the second semiconductor material, an electrode longitudinally spaced apart from the second sections, and forming a gap therebetween, and an electrolyte solution within the gap and surrounding the nanowires, the method comprising: using tunnel junctions extending between the first sections and the second sections of the nanowires, reducing built-in electric fields occurring within the nanowires; using a current detector having a first terminal electrically connected to the semiconductor substrate and a second terminal electrically connected to the electrode, detecting a given electrical current signal having a given polarity; and using a controller, generating a signal indicative that photons of either the first photon energy or the second photon energy have impinged on the nanowires based on the given polarity.

Further in accordance with the second aspect of the present disclosure, the tunnel junction can for example have a third section of a third semiconductor material extending from the first section of the nanowire, a fourth section of a fourth semiconductor material extending from the third section, and a fifth section of a fifth semiconductor material extending between the fourth section and the second section of the nanowire.

Still further in accordance with the second aspect of the present disclosure, the third semiconductor material can for example be an n++-type doped semiconductor material, and the fifth semiconductor material can for example be a p++-type doped semiconductor material.

Still further in accordance with the second aspect of the present disclosure, the n++-type doped semiconductor material can for example be an n++-type doped GaN, and the p++-type doped semiconductor material can for example be p++-type doped GaN.

All technical implementation details and advantages described with respect to a particular aspect of the present invention are self-evidently mutatis mutandis applicable for all other aspects of the present invention.

In this disclosure, the term “distinguishingly detect” is meant to encompass the action of not only detecting photons of different photon energies, but also distinguishing the photons of different photon energies from one another.

Many further features and combinations thereof concerning the present improvements will appear to those skilled in the art following a reading of the instant disclosure.

### DESCRIPTION OF THE FIGURES

In the figures,

FIG. 1 is a schematic view of an example of a photodetector device, shown forming a closed electrical circuit including a semiconductor substrate, nanowires, an electrolyte solution, an electrode, and a current detector, in accordance with one or more embodiments;

FIG. 2 is an oblique view of another example of a photodetector device detecting photons of different photon energies, in accordance with one or more embodiments;

FIG. 3 is a flow chart of example method of distinguishingly detecting photons of different bandgap energies using a photodetector device, in accordance with one or more embodiments;

FIG. 4 is a block diagram of a computing device of a controller, in accordance with one or more embodiments;

FIG. 5A is a schematic view of an electrical circuit of a photodetector device generating positive current generation upon receiving a first light beam, in accordance with one or more embodiments;

FIG. 5B is a schematic view of an electrical circuit of the photodetector device of FIG. 5A, the photodetector device generating negative current upon receiving a second light beam, in accordance with one or more embodiments;

FIG. 5C is a schematic view of the electrical circuit of FIG. 5B showing negative photocurrent quenching due to built-in electric fields occurring at the junction, in accordance with one or more embodiments;

FIG. 6A is scanning electron microscope (SEM) image showing an oblique view of an array of semiconductor nanowires, each semiconductor nanowire having an n-GaN/p-InGaN heterojunction, with the inset showing a schematic view of the semiconductor nanowire, in accordance with one or more embodiments;

FIG. 6B includes transmission electron microscope (TEM) studies of the semiconductor nanowires of FIG. 6A, with (i) showing dark field scanning TEM (STEM) image, (ii) showing corresponding indium signal mapping, and (iii) showing the corresponding gallium signal mapping, in accordance with one or more embodiments;

FIG. 6C is a graph showing room temperature (RT) photoluminescence (PL) spectra of the InGaN and GaN nanowire sections of FIG. 6A, in accordance with one or more embodiments;

FIG. 6D is an energy band diagram of the InGaN and GaN nanowire segments of FIG. 6A, showing bands of other semiconductor materials, in accordance with one or more embodiments;

FIG. 6E is a graph showing photoresponse of a photodetector device made with the heterojunction of FIG. 6A, measured in a 2-electrode configuration under 0 V, resulting in an excitation density of 1.6 mW cm⁻² and 7.5 mW cm⁻² for 302 nm and 405 nm, respectively, in accordance with one or more embodiments;

FIG. 7A is a schematic view of another example of a semiconductor nanowire having an InGaN nanowire, with the inset showing a schematic view of the n++-GaN/InGaN/p++-GaN tunnel junction, in accordance with one or more embodiments;

FIG. 7B includes dark field STEM images and the elemental mapping of the InGaN nanowire of FIG. 7A, with (i) showing the dark field image, (ii) showing dark field imaging overlapped with Ga, In, and N signals, (iii) showing Ga signal, and (iv) showing In signal, in accordance with one or more embodiments;

FIG. 7C is a graph showing Ga and In signals along the direction as shown by the arrow in FIG. 7B(ii), in accordance with one or more embodiments;

FIGS. 7D and 7E are graphs showing photoresponse of photodetector devices made with the p-doped InGaN TJ nanowire working electrode and the non-doped InGaN TJ nanowire working electrode of FIG. 7A, respectively, under the 302 nm and 405 nm light illumination, measured in a 2-electrode configuration, in accordance with one or more embodiments;

FIG. 7F is a schematic view of a photodetector device incorporating the InGaN nanowire of FIG. 7A, showing the energy band diagram and highlighting the p⁺⁺-GaN/p-InGaN interface, in accordance with one or more embodiments;

FIGS. 8A to 8C are graphs showing the characterization of a photodetector device having an InGaN tunnel junction nanowire working electrode and pt counter electrode immersed in an H₂SO₄ electrolyte solution, with FIG. 8A showing time-dependent photocurrent density under different light excitation power densities, FIG. 8B showing the extracted photocurrent density and responsivity versus the excitation, and FIG. 8C response and recovery time versus the excitation for 302 nm light illumination, respectively, in accordance with one or more embodiments;

FIGS. 8D to 8F are graphs showing the characterization of a photodetector device having an InGaN tunnel junction nanowire working electrode and pt counter electrode immersed in an H₂SO₄ electrolyte solution, with FIG. 8D showing time-dependent photocurrent density under different light excitation power densities, FIG. 8E showing the extracted photocurrent density and responsivity versus the excitation, and FIG. 8F response and recovery time versus the excitation for 405 nm light illumination, respectively, in accordance with one or more embodiments;

FIGS. 9A to 9C are graphs showing the characterization of a photodetector device having an InGaN tunnel junction nanowire working electrode and pt counter electrode immersed in an NaCl electrolyte solution, with FIG. 9A showing time-dependent photocurrent density under different light excitation power densities, FIG. 9B showing the extracted photocurrent density and responsivity versus the excitation, and FIG. 9C response and recovery time versus the excitation for 302 nm light illumination, respectively, in accordance with one or more embodiments;

FIGS. 9D to 9F are graphs showing the characterization of a photodetector device having an InGaN tunnel junction nanowire working electrode and pt counter electrode immersed in an NaCl electrolyte solution, with FIG. 9D showing time-dependent photocurrent density under different light excitation power densities, FIG. 9E showing the extracted photocurrent density and responsivity versus the excitation, and FIG. 9F response and recovery time versus the excitation for 405 nm light illumination, respectively, in accordance with one or more embodiments;

FIG. 10A is a schematic view of an example UWSN having nodes including submarines, ships, and integrated photodetector nodes, in accordance with one or more embodiments;

FIG. 10B is a schematic view of an experimental setup to mimic the data transmission in UWSNs, in accordance with one or more embodiments; and

FIG. 10C is a graph showing photocurrent measured from an example photodetector device distinguishing wavelengths, with shaded regions denoting the photocurrent measured and the deciphered binary bits, in accordance with one or more embodiments.

### DETAILED DESCRIPTION

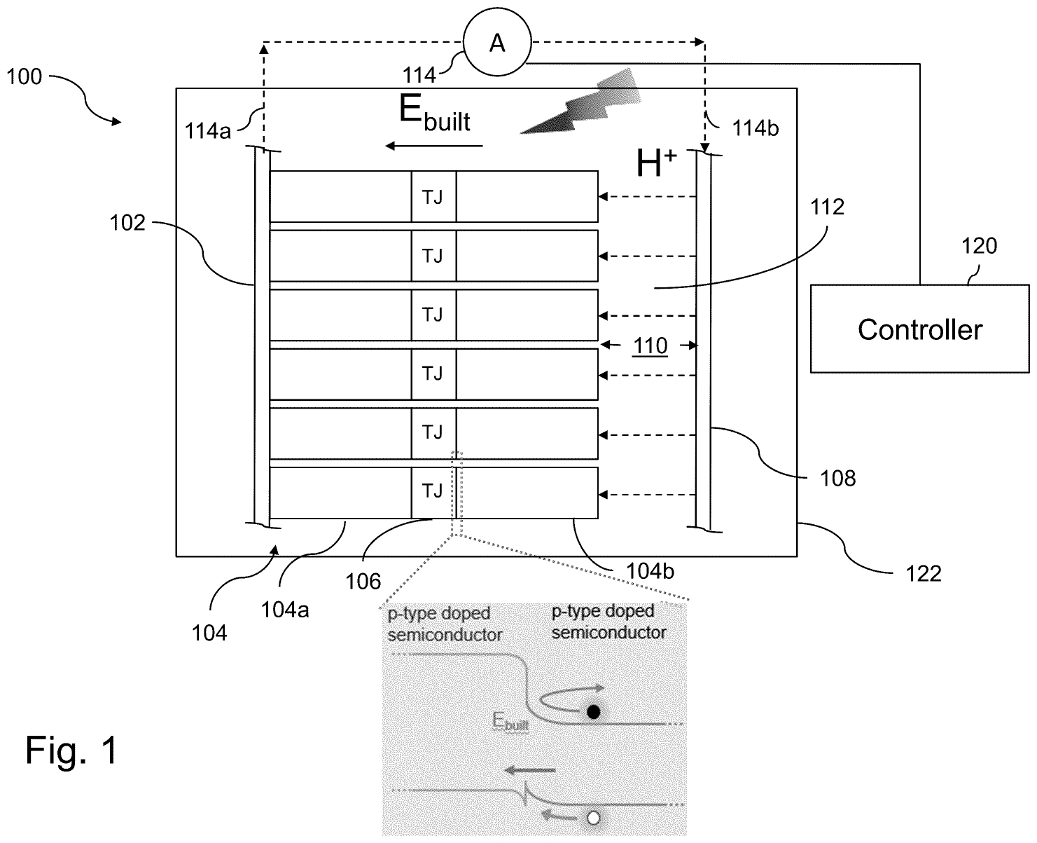

FIG. 1 shows an example of a photodetector device 100, in accordance with an embodiment. As depicted, the photodetector device 100 has a semiconductor substrate 102 from which nanowires 104 extend. Each nanowire 104 has a first section 104a of a first semiconductor material extending from the semiconductor substrate 102, a tunnel junction 106 extending from the first section 104a, and a second section 104b of a second semiconductor extending from the tunnel junction 106. As will be discussed further below, the first semiconductor material has a first bandgap energy different from a second bandgap energy of the second semiconductor material. As such, the nanowires 104 form semiconductor heterojunctions. An electrode 108 is longitudinally spaced apart from the second sections 104b of the nanowires 104, and forms a gap 110 between the second sections 104b and the electrode 108. As illustrated, an electrolyte solution 112 lies within the gap 110 and surrounds the nanowires 104. During use, an electrical circuit is formed. The electrical circuit includes the semiconductor substrate 102, the nanowires 104, the electrolyte solution 112 filling the gap 110 and surrounding the nanowires 104, the electrode 108 and a current detector 114 which has a first terminal 114a electrically connected to the semiconductor substrate 102 and a second terminal 114b electrically connected to the electrode 108.

As discussed briefly above, and in greater detail below, the presence of a tunnel junction 106 in each of the nanowires 104 allows the reduction of built-in electric fields E_{built} occurring within the nanowires 104 when submerged into the electrolyte solution 112 and/or under light exposure. During use, the current detector 114 can detect a first electrical current signal when first photons having a first photon energy exceeding the first bandgap energy impinge at least on the first sections 104a of the nanowires 104. Additionally or alternately, the current detector 114 can detect a second electrical current signal when second photons having a second photon energy exceeding the second bandgap energy impinge at least on the second sections 104b of the nanowires 104. In these embodiments, it is intended that the first electrical current signal has a polarity different from a polarity of the second electrical current signal. For instance, if the polarity of the first electrical current is a positive polarity, the polarity of the second electrical current is a negative polarity, or vice versa.

In some embodiments, a controller 120 is communicatively coupled to the current detector 114. The communication can be wired, wireless, or a combination of both. The controller 120 generally has a processor and a non-volatile computer memory having stored thereon instructions that when executed by the processor perform some predetermined steps. In certain embodiments, the controller 120 generates a signal indicative that photons of the first photon energy have impinged on the nanowires. The controller 120 can also generate a signal indicative that photons of the second photon energy have impinged on the nanowires 104. In this way, the resulting photodetector device 100 can distinguish photons of different wavelengths, frequencies and photon energies.

In the illustrated embodiment, an enclosure 122 is provided to enclose the semiconductor substrate 102, the nanowires 104, the electrode 112 and the electrolyte solution 112. The current detector 114 can have some terminal portions immersed within the electrolyte solution 112. However, as shown, the remainder of the current detector 114 needs not to be within the electrolyte solution 112. In some other embodiments, the enclosure 122 can be omitted as the photodetector device 100 can be submerged in a body of water (e.g., ocean water), acting as the electrolyte solution 112. The electrolyte solution 112 can contain a number of different ions such as K⁺, Mg²⁺, Ca²⁺, Br, SO₄²⁻, and CO₃²⁻, or a combination thereof. For instance, the electrolyte solution can be a mix of water and a sodium chloride (NaCl) in some embodiments.

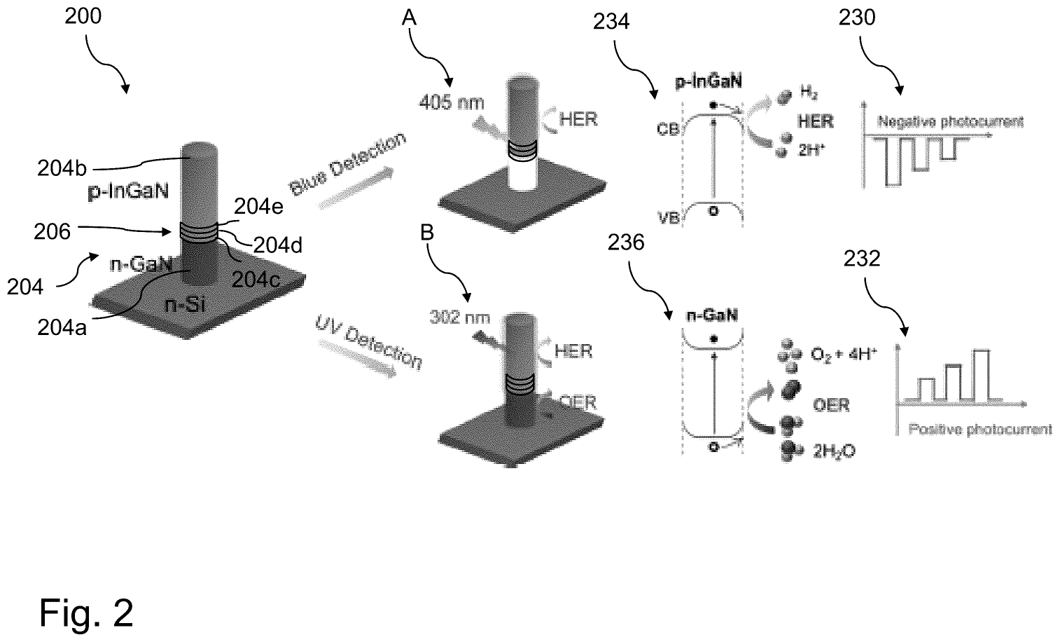

Referring now to FIG. 2, another example of a photodetector device 200 is shown. As depicted, the first semiconductor material of the first section 204a is provided in the form of an n-type doped semiconductor material. The second semiconductor material of the second section 204b is a p-type doped semiconductor material. More specifically, in this specific embodiment, the n-type doped semiconductor material is an n-type doped gallium nitride (GaN), and the p-type doped semiconductor material is a p-type doped indium gallium nitride (InGaN).

Regarding the tunnel junction 206, in this example, it is provided with a third section 206c of a third semiconductor material extending from the first section 204a of the nanowire 204, a fourth section 204d of a fourth semiconductor material extending from the third section 204c, and a fifth section 204e of a fifth semiconductor material extending between the fourth section 204d and the second section 204b of the nanowire 204. In this specific embodiment, the third semiconductor material is an n++-type doped semiconductor material and the fifth semiconductor material is a p++-type doped semiconductor material. More specifically, the n++-type doped semiconductor material is an n++-type doped GaN, and the p++-type doped semiconductor material is p++-type doped GaN. In some embodiments, such as the one illustrated, the second semiconductor material of the second section 204b of the nanowire 204 and the fourth semiconductor material of the tunnel junction 206 are provided in the form of a similar semiconductor material which can be (InGaN) in some illustrated embodiments. In some embodiments, the similar semiconductor material can be indium nitride (InN). In this case, the excitation wavelength can be 632 nm, which is transparent to GaN, but opaque to InN. In some embodiments, it can be AlGaN. In this latter case, the excitation wavelength can be 266 nm, which is transparent to AlGaN, but opaque to GaN.

As depicted, when first photons A of a first photon energy corresponding to blue light (e.g., around 405 nm) impinge the nanowire 204, a negative photocurrent 230 is generated along the electrical path of the corresponding photodetector device 200, which can be measured by the current detector. However, when second photons B of a second photon energy corresponding to UV (e.g., around 302 nm or below) impinge the nanowire 204, a positive photocurrent 232 is generated along the electrical path of the corresponding photodetector device 200, which can also be measured by the current detector. Thanks to the presence of the tunnel junction 206, the positive photocurrent and the negative photocurrent can be discernible from one another as they are not partially or wholly degenerate from one another due to built-in electrical fields generally occurring within conventional nanowires. As discussed below, the electrolyte solution helps close the electrical path into a closed electrical circuit thanks to a hydrogen evolution reaction (HER) 234 or an oxygen evolution reaction (OER) 236 that are triggered based on the wavelength of the incoming photons. The photodetector device 200 allows to not only detect two (or more) different photon energies, but to also distinguish photons of different photon energies from one another. As described herein, the detection and distinguishing of the photons of different photon energies is performed along the same electrical path, and monitored by the same current detector (e.g., an amperemeter).

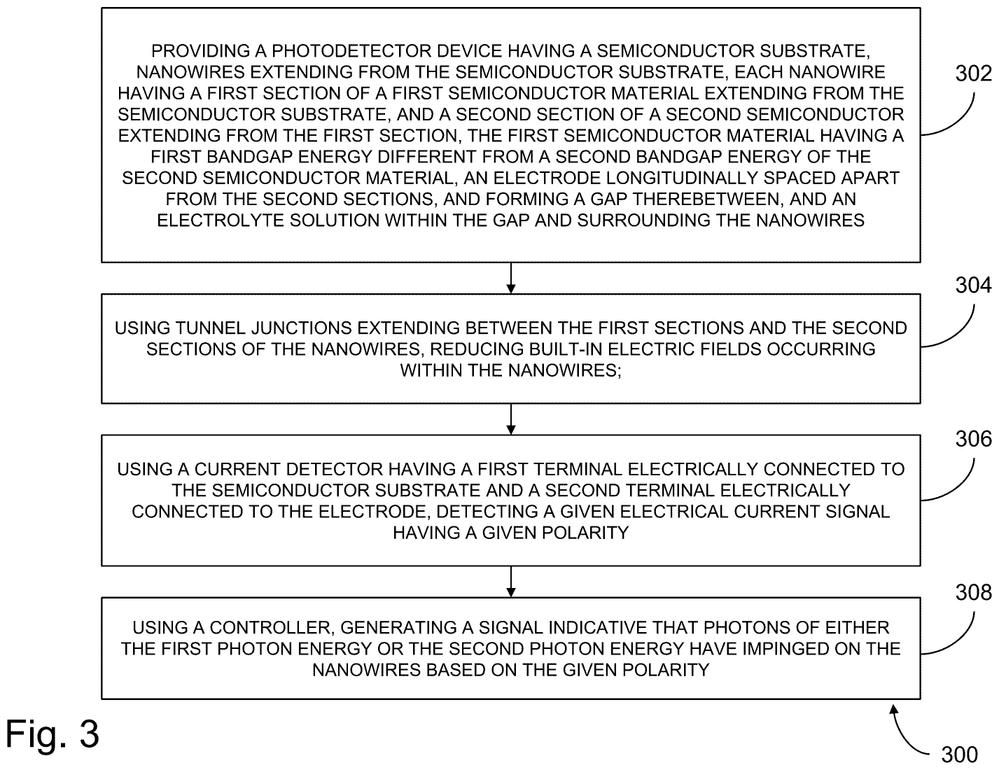

FIG. 3 shows a flow chart of a method 300 of distinguishingly detecting photons of different bandgap energies using a photodetector device such as the photodetector device of FIG. 1.

At step 302, there is provided a photodetector device such as discussed above and below. The photodetector device has a semiconductor substrate, and nanowires extending from the semiconductor substrate. Each nanowire has a first section of a first semiconductor material extending from the semiconductor substrate, and a second section of a second semiconductor extending from the first section. The first semiconductor material has a first bandgap energy different from a second bandgap energy of the second semiconductor material. The photodetector device is also provided with an electrode longitudinally spaced apart from the second sections of the nanowires so as to form a gap therebetween. The semiconductor substrate, the nanowires and the electrode are all immersed in electrolyte solution so that the electrolyte solution fills the gap and surrounds the nanowires during use.

As shown, at step 304, tunnel junctions extending between the first sections and the second sections of the nanowires are used to reduce the built-in electric fields occurring within the nanowires when light is shined upon the nanowires.

At step 306, a current detector having a first terminal electrically connected to the semiconductor substrate and a second terminal electrically connected to the electrode is used to detect a given electrical current signal having a given polarity.

At step 308, a controller is used to generate a signal indicative that photons of either the first photon energy or the second photon energy have impinged on the nanowires based on the given polarity of the given electrical current signal. For instance, if the given polarity is positive, then it can be determined that the detected photons have a first photon energy. If the given polarity is negative, then it can be determined that the detected photons have a second photon energy different from the first photon energy. Referring back to FIG. 2, if the given polarity is negative, then it can be determined that the first photon energy corresponds to blue photons (e.g., of a wavelength of about 405 nm). In other situations, for instance if the given polarity is positive, then it may be determined that the second photon energy corresponding to ultraviolet (UV) photons (e.g., of a wavelength of 302 nm or below).

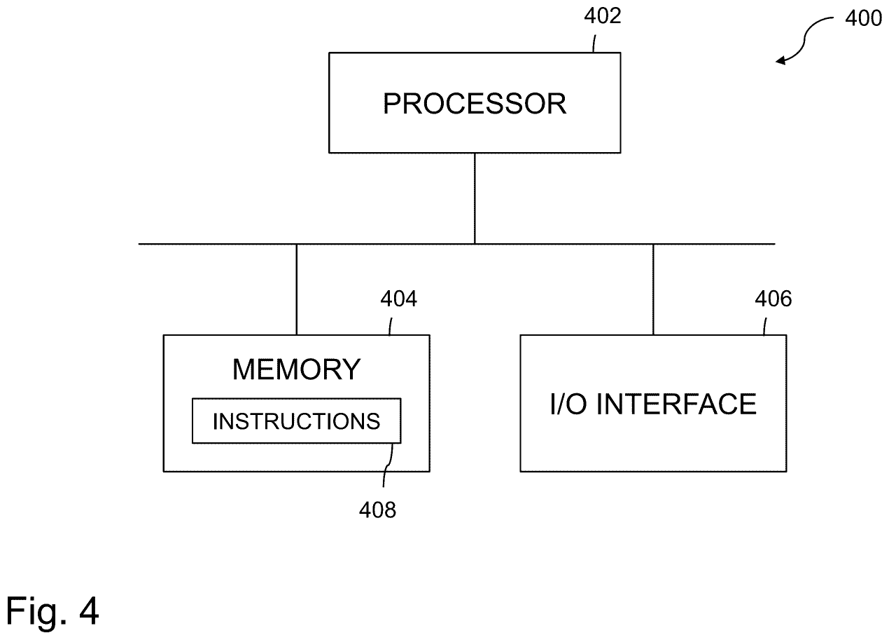

Referring now to FIG. 4, the controller of the system of FIG. 1 can be provided as a combination of hardware and software components. The hardware components can be implemented in the form of a computing device 400, an example of which is described with reference to FIG. 4. The computing device 400 can have a processor 402, a memory 404, and I/O interface 406. Instructions 408 for detecting different photon energies can be stored on the memory 404 and accessible by the processor 402.

The processor 402 can be, for example, a general-purpose microprocessor or microcontroller, a digital signal processing (DSP) processor, an integrated circuit, a field-programmable gate array (FPGA), a reconfigurable processor, a programmable read-only memory (PROM), a programmable logic controller (PLC), or any combination thereof.

The memory 404 can include a suitable combination of any type of computer-readable memory that is located either internally or externally such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like.

Each I/O interface 406 enables the computing device 400 to interconnect with one or more input devices, or with one or more output devices.

Each I/O interface 406 enables the controller to communicate with other components, to exchange data with other components, to access and connect to network resources, to server applications, and perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fibre optics, satellite, mobile, wireless (e.g. Wi-Fi, WiMAX), SS7 signaling network, fixed line, local area network, wide area network, and others, including any combination of these.

The computing device 400 and any software application that can be ran by the computing device 400 are meant to be examples only. Other suitable embodiments of the controller can also be provided, as it will be apparent to the skilled reader.

### EXAMPLE 1

### Breaking the Built-in Electric Field Barrier in p-n Heterojunction for Self-powered, Wavelength Distinguishable Photoelectrochemical Photodetectors

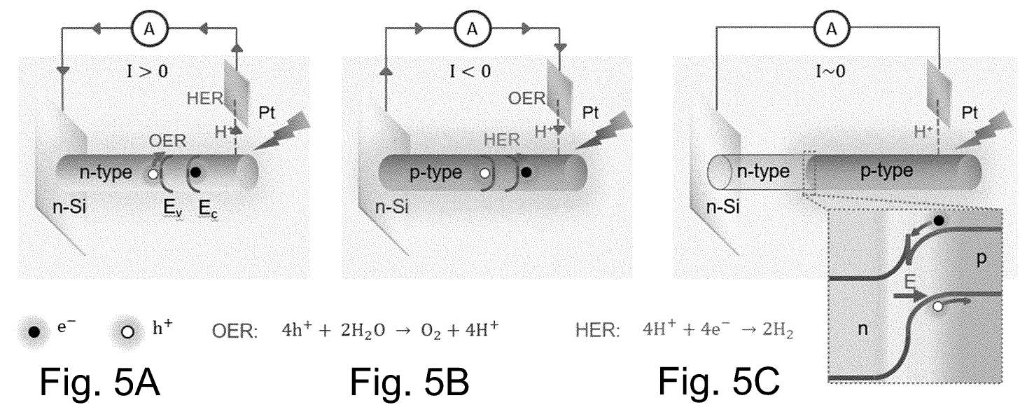

Semiconductor p-n heterojunction is an emerging route to self-powered, wavelength distinguishable PEC-PDs. One basic principle of using p-n heterojunction for wavelength distinguishable photodetection is to utilize the polarity of the photocurrent to sense different incident light wavelengths, based on different types of chemical reactions occurring on the semiconductor-electrolyte interface under the light illumination. For n-type semiconductors, due to the upward band bending, the hole transfer process leads to oxygen evolution reaction (OER) and consequently positive photocurrent (FIG. 5A), whereas the hydrogen evolution reaction (HER) occurring on the p-type semiconductor-electrolyte interface due to the downward band bending leads to negative photocurrent (FIG. 5B). As such, in a nutshell, if choosing semiconductor p-n heterojunction with proper bandgap energies, wavelength distinguishable light detection can be made possible by sensing the polarity of the photocurrent.

Yet, there have not had any devices demonstrated. One critical issue is related to the built-in electric field at the junction. For example, in the working electrode configuration as shown in FIG. 5C (n-down, p-up), due to the built-in electric field at the junction, HER is more difficult to happen (Note: it is a 2-electrode PEC cell), limiting the negative photocurrent. This is because the built-in electric field could have a photovoltaic (PV) effect similar to a solar cell, i.e., upon light illumination on the p-side (whereas n-side remains transparent), the built-in electric field tends to separate the photogenerated electrons and holes near the p-n junction and sweep photogenerated electrons to n-side and photogenerated holes to p-side, making it difficult for HER to occur on the p-side and holes transport to the substrate. Although this could lead to abnormal photocurrent which might be favorable for certain applications, this illustrates the generic difficulty of generating negative photocurrent in the working electrode with the n-down, p-up configuration in a 2-electrode PEC cell, which further limits the achievement of wavelength distinguishable light detection. This also means, in order to achieve wavelength distinguishable light detection, improving the HER process on the working electrode is necessary. Vice versa, for the p-down, n-up working electrode configuration, the built-in electric field would hinder OER process and positive current generation. This analysis illustrates the difficulty in achieving self-powered, wavelength distinguishable PEC-PDs using p-n junction working electrode, which is originated from the built-in electric field at the junction.

In this example, it was demonstrated that by integrating tunnel junction into semiconductor nanowire p-n heterojunction, the adverse effect of the built-in electric field can be greatly reduced, which leads to the achievement of the first self-powered, wavelength distinguishable PEC-PDs using a single photoelectrode, i.e., one photoelectrode is able to detect two different light wavelengths without using any external electrical power. In a specific embodiment, by using a working electrode made with n-GaN/p-InGaN p-n heterojunction nanowires in which n++-GaN/InGaN/p++-GaN tunnel junction is embedded, self-powered, wavelength distinguishable PEC-PDs in the visible (405 nm) and UV (302 nm) are obtained, with high responsivities in the mA/W range. Moreover, the electrolyte for such self-powered, wavelength distinguishable PEC-PDs can be either acidic or NaCl, making them potentially suited for optical wireless communication in the ocean environment. Enhanced data transmission security leveraging such wavelength distinguishable, self-powered PEC-PDs is further demonstrated in the end in the data transmission process mimicking that occurs in an UWSN.

PEC-PDs wherein the working electrode is made n-GaN/p-InGaN p-n heterojunction nanowires, without the tunnel junction, are described first. The detailed growth condition for the heterojunction nanowires can be found in the next paragraphs.

Regarding molecular beam epitaxy, all the nanowire samples in the present example were grown on 3-inch n-Si (111) substrates using molecular beam epitaxy (MBE) in nitrogen-rich conditions. To achieve p-type and n-type electrical doping, Mg and Si were used, respectively. The estimated n-type and p-type doping concentrations were ˜10¹⁹ cm⁻³. The n-GaN nanowire segment was grown at a substrate temperature of 730° C., with a Ga beam equivalent pressure (BEP) of approximately 7.7×10⁻⁸ Torr and a nitrogen flow rate of 1.5 sccm. The substrate temperature is estimated by the Si (111) surface reconstruction during the heating process. For the p-InGaN nanowire segment, the substrate temperature was approximately 130° C. lower, while the Ga BEP was 2.4×10⁻⁸ Torr, and the In BEP was around 2.2×10⁻⁸ Torr. For the n++-GaN/InGaN/p++-GaN tunnel junction (TJ), the substrate temperature was 610° C. The estimated thickness from each layer, based on a separate calibration of the growth rate, was 15 nm, 5 nm, and 20 nm for the n++-GaN, InGaN, and p++-GaN layers, respectively.

Regarding photoelectrode preparation and PEC tests, PEC measurements were performed in a 2-electrode configuration, in which the reference port of the potentiostat was short-circuited with the counter electrode. Pt was the counter electrode. The electrolyte was either 0.5 M H₂SO₄ or 24.3 g L⁻¹ NaCl. Deionized water (DI) was used to prepare the electrolytes. To establish electrical conduction, copper tape was affixed to the backside of the silicon substrate, and insulating epoxy was used to define the dimensions of the nanowire photoelectrode. The surface area of the photoelectrodes utilized in this example ranged approximately from 0.5 to 0.6 cm². For the PEC experiments, a 405 nm uncollimated blue laser diode was employed as the excitation light source. The spot size was controlled by a focus lens. A 302 nm UV lamp was used as the second excitation light source. PEC measurements, including linear sweep voltammetry (LSV) and chronoamperometry (time-dependent photocurrent), were conducted using the Gamry 1000 potentiostat.

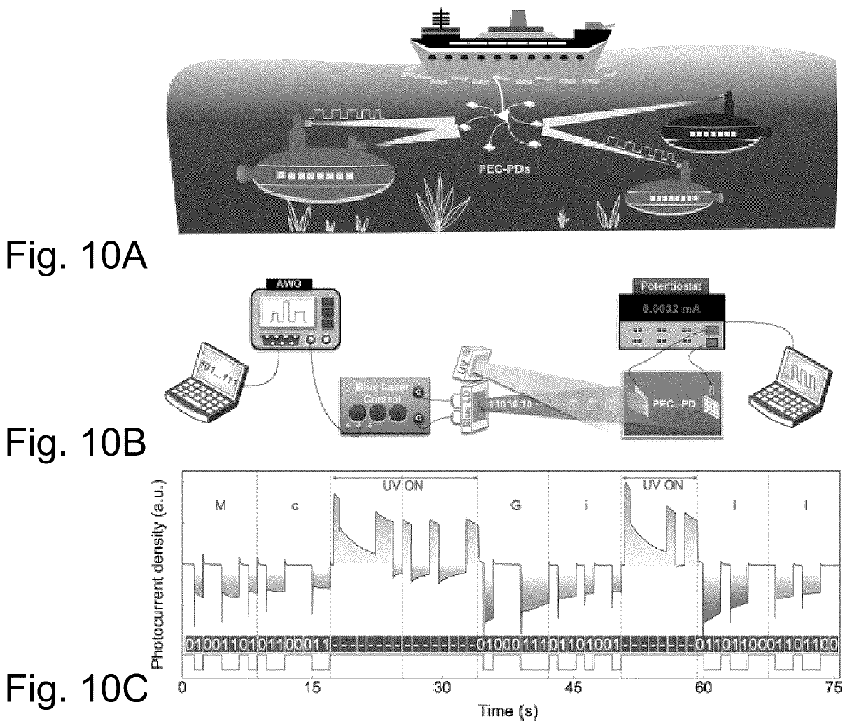

Regarding signal transmission and processing, in order to generate the signals for transmission with a 405 nm laser diode, MATLAB® was utilized to convert random text into binary code. Based on the code, Test Script Processing® language from Keithley® was used to guide a Keithley 2651A SourceMeter (denoted as “AWG” in FIG. 10B) via NI-VISA connection to generate voltage signals accordingly. The voltage signals were subsequently used to drive to a Thorlabs® LDC210C Benchtop LD Current Controller to modulate the 405 nm laser diode.

Regarding decoding, homemade MATLAB® codes were developed to regenerate the binary sequence based on the collected time-dependent photocurrent by the PEC-PDs.

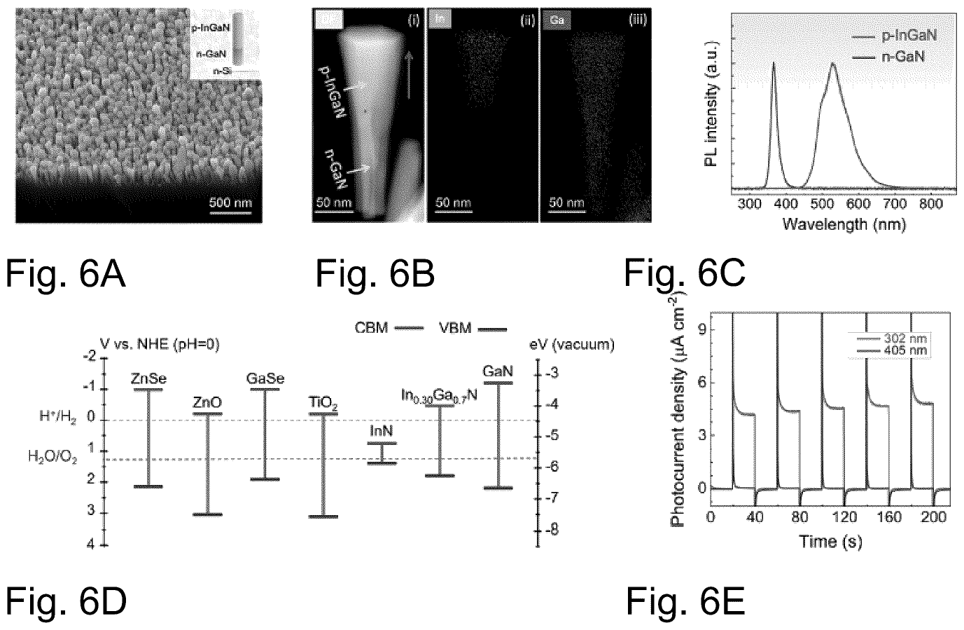

A scanning electron microscopy (SEM) image of such heterojunction nanowires is shown in FIG. 6A, with the nanowire schematic shown in the inset. The SEM image was taken at a wafer tilting angle of 45 degrees. The heterojunction nanowires are further examined by transmission electron microscopy (TEM). Shown in FIG. 6B are the dark field scanning-TEM (STEM) images of a heterojunction nanowire as well as the corresponding elemental mapping of Ga and In. The n-GaN and p-InGaN segments are clearly seen, confirming the formation of an axial heterojunction. Detailed high resolution TEM studies further confirm that such heterojunction nanowires have excellent crystalline quality in both segments.

The room temperature (RT) photoluminescence (PL) spectra of the InGaN and GaN nanowire segments are shown in FIG. 6C. The PL peak around 530 nm suggests that the InGaN nanowire segment has an In content of around 27-30 mol. % using the Vegard's law. This is consistent with the In molar fraction analysis using XPS. In addition, the incorporation of Mg is also confirmed by XPS experiments. The PL peak around 364 nm is attributed to the light emission from the GaN nanowire segment. As such, for both InGaN and GaN nanowire segments, their band edges straddle the water redox potentials, and can in principle support both HER and OER reactions (FIG. 6D). In this example, focus is put on HER for InGaN and OER for GaN, due to the respective p-type and n-type doping. In the meantime, the proper band energies allow photon absorption when 405 nm and 302 nm, the two light wavelengths used in this example, are applied. Also shown in FIG. 6D is the conduction and valence band edges of a few other commonly used semiconductor materials for photoelectrodes.

The photoresponse of such PEC-PDs is further studied in a 2-electrode configuration. The electrolyte is 0.5 M H₂SO₄ and the counter electrode is Pt. FIG. 6E shows the time-dependent photocurrent under the 302 nm and 405 nm light illumination at 0 V. Under the 302 nm light illumination, both n-GaN and p-InGaN segments absorb the light. For the n-GaN segment, the OER reaction can lead to a positive current, whereas for the p-InGaN segment, the HER reaction can lead to a negative current. However, due to the presence of the built-in electric field (as explained earlier), HER will not be favorable, which in consequence leads to a net positive photocurrent. Under the 405 nm light illumination, the light absorption occurs only in the p-InGaN. In this case, in principle, negative photocurrent is expected; nonetheless, due to the built-in electric field, such a negative photocurrent is hindered, ultimately leading to a near zero photocurrent. The existence of the photocurrent spike when the light turns on could be related to a transient current, and the mechanism is being investigated. Since the photoresponse increases with the light excitation, and the above photoresponse is measured under the highest excitation, this means that self-powered wavelength distinguishable photodetection is not achieved, limited by the difficulty in obtaining negative photocurrent due to the unfavorable built-in electric field.

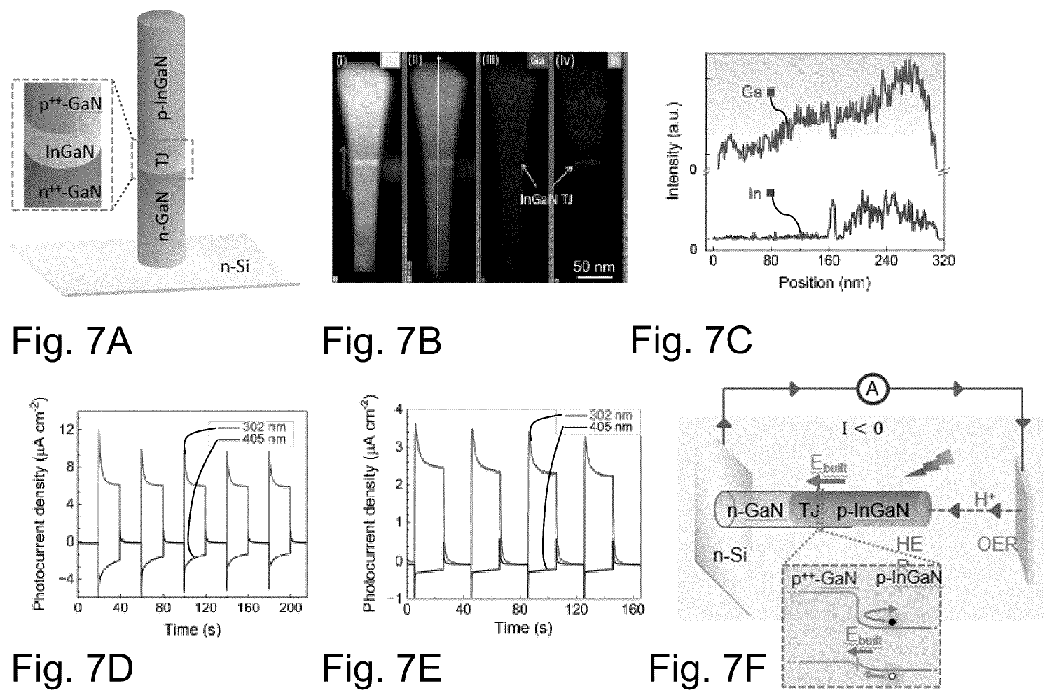

In the following example, it will be shown that by incorporating tunnel junction (TJ) into the same p-n heterojunction photoelectrode, self-powered, wavelength distinguishable photodetections can be realized in 2-electrode configuration, i.e., self-powered, wavelength distinguishable PEC-PDs can be achieved. The structure of the TJ InGaN nanowire photoelectrode is schematically shown in FIG. 7A, which consists of the same p-InGaN and n-GaN nanowire segments but with an n++-GaN/InGaN/p++-GaN TJ incorporated. FIG. 7B shows the dark field STEM image of a single TJ InGaN nanowire (FIG. 7B(i)), as well as the Ga and In elemental mapping (FIGS. 7B(ii), 7B(iii) and 7B(iv)), whereas the Ga and In signals along the direction as indicated in FIG. 7B(ii) are shown in FIG. 7C. It is seen that the InGaN layer in the TJ is clearly seen, and the n-GaN and p-InGaN segments are also clearly seen, confirmation the formation of the desired structure.

The time-dependent photocurrent of such PEC-PDs, made with Pt counter electrode in H₂SO₄ electrolyte, under the UV (302 nm) and blue (405 nm) light illumination, is shown in FIG. 7D. It is seen that, both negative (under 405 nm light illumination) and positive photocurrents (under 302 nm light illumination) are measured at 0 V, i.e., self-powered, wavelength distinguishable photodetection is achieved, thanks to obtaining the negative photocurrent under the 405 nm light illumination (which is not the case for devices without the TJ). The mechanism of obtaining the negative photocurrent under the 405 nm light illumination can be understood by the schematic shown in FIG. 7F. At the p++-GaN/p-InGaN interface, the build-in electric field is in the opposite direction comparing to that at the n-GaN/p-InGaN interface (it is noted that for the n-GaN/n++-GaN interface of the TJ, the electric field is also in the opposite direction); as such, the PV effect is now essentially favorable for HER, i.e., the built-in electric field will sweep photogenerated electrons to p-InGaN (or nondoped InGaN) and photogenerated holes to the p++-GaN. Moreover, the large potential barrier at the p++-GaN/p-InGaN interface will block the transport of photogenerated electrons to the substrate, which also enhances HER. Ultimately, the negative photocurrent under the 405 nm light illumination is obtained. In other words, FIG. 7F shows a photodetector device having an architecture which can provide a self-powered capability and a wavelength distinguishable detection functionality. The main components include: a nanowire photoelectrode having a first section, for wavelength A, a second section for wavelength B and a tunnel junction for photocarrier dynamics tuning. As discussed herein, the inventors have found that by integrating such a tunnel junction to reduce built-in electric field occurring within the nanowire photoelectrode, signals of different polarity could be more easily detectable. Other features that are worthy of mention are the spaced-apart electrode being made of metal, the use of only two electrodes (the semiconductor substrate and the extending nanowires and the spaced-apart electrode), the omitting of a third reference electrode (that may be active), the electrolytic environment, and a current detector as a passive component to sense positive/negative photocurrents, which can then be correlated to two different wavelengths. In some embodiments, it is intended that the semiconductor materials of the first and second sections can be extended to other materials for a broader wavelength range, only limited by the optical bandgap of group-III nitrides (200 nm to 2,000 nm). Additionally or alternatively, quantum dots, quantum disks and the like can also be further included in the first and/or section sections of the nanowires.

Comparison of devices with and without the TJ suggests that TJ can effectively overcome the negative role of the built-in electric field in semiconductor p-n junction in achieving self-powered, wavelength distinguishable PEC-PDs. In fact, phenomenally, self-powered, wavelength distinguishable light detection is even achievable in PEC-PDs made with nondoped InGaN nanowire working electrode when TJ is incorporated (FIG. 7E), although nondoped InGaN nanowires have a weakly n-type surface, which is confirmed by XPS experiments. As such, it suggests that comparing to the downward surface band bending, TJ plays a greater role in driving HER, consequently negative photocurrent, and eventually self-powered, wavelength distinguishable photodetection.

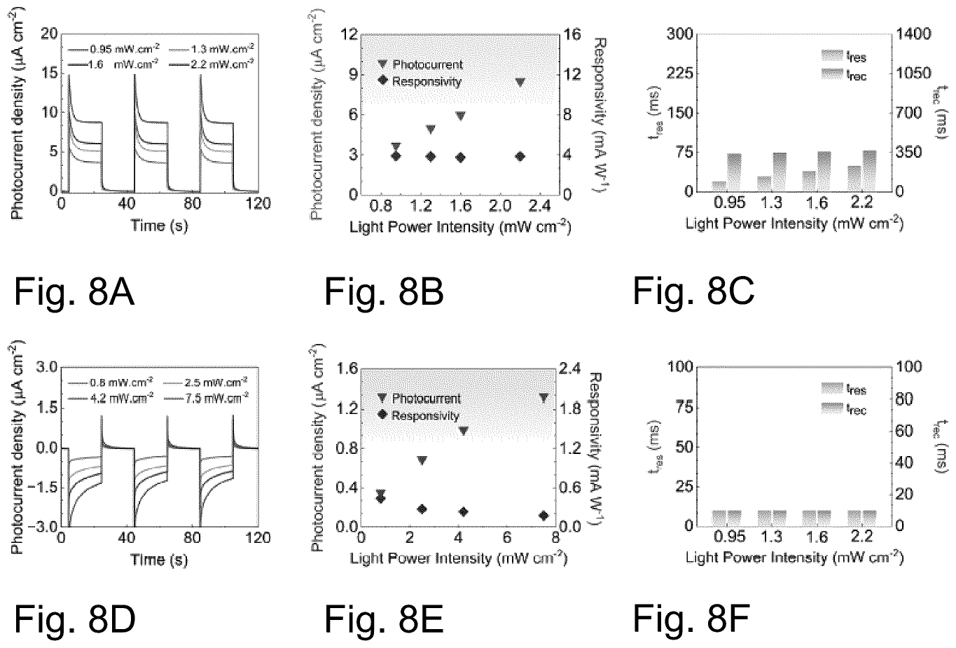

More detailed photoresponse of such self-powered, wavelength distinguishable PEC-PDs is shown in FIG. 8. FIGS. 8A to 8C show the results under the 302 nm light illumination, including the time-dependent photocurrent, extracted photocurrent density and responsivity versus the light excitation, and the response and the recovery time versus the light excitation. FIGS. 8D to 8E show similar plots but for the 405 nm light illumination. It is seen that for both incident wavelengths, the photocurrent density increases as the excitation increases and nearly stable photocurrent can be obtained. It should be noted that, the decrease of the photocurrent when the light is on does not reflect the device degradation, as the photocurrent in each cycle can be repeated. In fact, a one-hour long test was performed, and devices did not show any degradation. The mechanism of this light on transient behavior is being investigated. For 302 nm, a responsivity of around 4 mA/W is achieved, whereas for 405 nm, a responsivity of around 0.5 mA/W is obtained. Strategies such as increasing p-InGaN segment length, increasing In content, surface passivation or using platinum nanoparticles could potentially improve the responsivity for the blue light detection. These responsivities are comparable to the previously reported self-powered, wavelength distinguishable PEC-PDs in the UV and blue range with two photoelectrodes.

With respect to the response time (tᵣₑₛ), it is defined as the time needed for the photocurrent to increase from 10% to 90% of its maximum value; while for the recovery time (t_{rec}), it is defined as the period needed for the photocurrent to decrease from 90% to 10% of its maximum value. It is seen that, for the 302 nm illumination, tᵣₑₛ of 35 ms and t_{rec} of 355 ms can be obtained; whereas the for the 405 nm illumination, both tᵣₑₛ and t_{rec} are limited by the instrumentation, which is 10 ms, suggesting that the actual tᵣₑₛ and t_{rec} are less than 10 ms. The large t_{rec} under the 302 nm light illumination could be related to hole accumulation on the surface.

We have further tested the photoresponse of PEC-PDs made with the same TJ InGaN nanowire working electrode and Pt counter electrode but in NaCl electrolyte, given the potential application of such PEC-PDs in ocean environment, due to their electrolyte-based nature. While natural seawater consists of several other ions, including K+, Mg2+, Ca2+, Br−, SO42−, and CO32−, NaCl is the predominant component. In this regard, NaCl electrolyte could be considered to mimic the seawater environment.

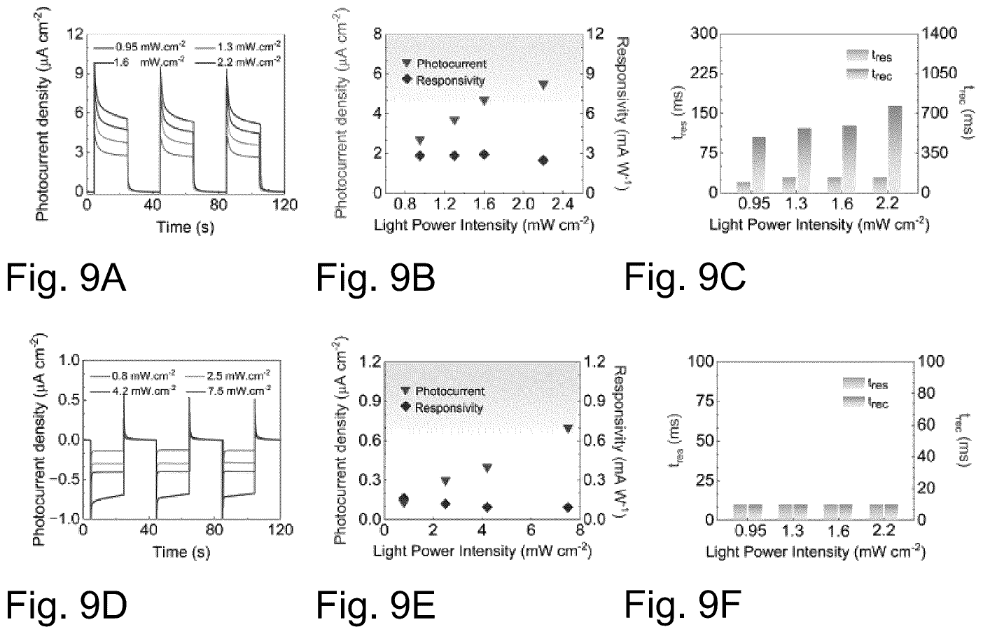

The device performance in this case is shown in FIG. 9. Overall, similar performance compared to using H₂SO₄ electrolyte is obtained, except that the responsivity is slightly reduced: for the 302 nm light illumination, the responsivity is around 3 mA/W; and for the 405 nm light illumination, the responsivity is up to around 0.2 mA/W. The reduced responsivity could be attributed to several factors, such as the conductivity of the electrolyte, redox species concentration, redox potential, and so on. Nonetheless, the response and recovery time have remained identical compared to using H₂SO₄ electrolyte, i.e., for the 405 nm light illumination, the device remains ultrafast and the photoresponse is mainly limited by the resolution of the instrumentation; and for the 302 nm light illumination, tᵣₑₛ and t_{rec} are around 25 ms and 605 ms, respectively

### EXAMPLE 2

### Towards Low Power Consumption and Secure Underwater Wireless Sensor Network (UWSN)

Developing a robust, secure, and low energy consumption UWSN is a pressing need for applications such as ocean environment monitoring, which has become increasingly important every day. Self-powered, wavelength distinguishable photodetector devices are appealing components to build the needed UWSNs, as the self-powered operation can significantly reduce the energy consumption and maintenance cost in operating UWSNs, whereas the wavelength distinguishability allows complex data encryption when transmitting it using light. Comparing PDs across various operation principles, self-powered, wavelength distinguishable photodetection is more achievable with PEC-PDs, due to their unique operation principle based on physical and chemical processes occurring at semiconductor and electrolyte interface and the consequently superior flexibility in tuning the photoresponse. However, achieving self-powered, wavelength distinguishable PEC-PDs remains a challenge. At this point, it should be noted that, a photoelectrode with photoresponse under zero potential versus a reference electrode in a three-electrode configuration does not necessarily make it a self-powered PEC-PD, due to the potential applied by the potentiostat between the photoelectrode and counter electrode.

In this example, there was demonstrated that such self-powered, wavelength distinguishable PEC-PDs can allow a significantly enhanced data transmission security compared to using conventional, wavelength indistinguishable photodetectors in an UWSN. For instance, FIG. 10A depicts the concept of an UWSN in ocean environment, which consists of a vast number of nodes working collaboratively to monitor, detect, and track various events and objects in the underwater environment. As will be shown below, integrating the present wavelength distinguishable PEC-PDs in nodes can significantly enhance the data transmission security in the UWSN.

To illustrate the enhanced data transmission security, the intended characters “McGill” are transmitted with the setup shown in FIG. 10B, to mimic the data transmission in an UWSN. First, random extra characters, such as “y”, “n”, and “z” are inserted within the word “McGil” at arbitrary positions for encryption purpose, resulting in an altered word “McynGizll”. This encrypted word is then transformed into binary code following the extended ASCII scheme, which is further used to drive an arbitrary wave generator (AWG) to generate the corresponding voltage signals. The voltage signals are in the end sent to a laser controller to modulate the blue laser diode (405 nm) to transmit the encrypted word (i.e., “McynGizll”). An On-Off Keying method is used for data transmission with the blue light.

While the encrypted word is transmitted by the blue light, UV light is turned on when the random characters for encryption purpose are being transmitted. As such, for the intended receivers with the present wavelength distinguishable PEC-PDs, they could retrieve the intended word by ignoring signals related to UV light. On the other hand, for eavesdroppers who use wavelength indistinguishable PEC-PDs, as they do not know which signals to drop, they could not retrieve the intended message.

FIG. 10C shows the measured photocurrent from the present PEC-PDs when “McynGizll” is transmitted by the blue light (signaled by the negative photocurrent) and the UV light is turned on when extra characters (i.e., y”, “n”, and “z”) are being transmitted (signaled by the positive photocurrent). As the UV light induces a higher magnitude of photocurrent compared to the blue light, the inserted characters are associated with positive photocurrent. The initial higher negative photocurrent related to “G” and first “I” could be related to the transient when the UV light is off and blue light is on. As such, intended receivers with the present PEC-PDs can retrieve the intended word “McGill” by ignoring signals related to positive photocurrent. On the other hand, eavesdroppers who use wavelength indistinguishable PEC-PDs will not know which signal to drop as only monopolar photocurrent can be measured and thus could not intercept the message.

It is noted, though, even with the present PEC-PDs, one may not decode character “y” due to the interruption caused by UV light; however, one with such PEC-PDs can simply ignore signal related to positive photocurrent and retrieve the intended characters. As such, it provides a simple way to secure the data transmission. It should also be noted that, the example shown here is to illustrate the benefits of wavelength distinguishable PEC-PDs in improving data transmission security compared to their wavelength indistinguishable counterparts; and for advanced applications, it might need to integrate with additional encryption. For example, one may argue that the word “McGill” could still be discernible, due to the inherent sequence of the characters remains. To mitigate this, one can simply add additional encryption prior to inserting random characters, such as Base64 encryption. In this case, “McGill” will be converted to “TWNHaWxs”, and after inserting the random characters, the encrypted word will be “TacWNHTaWxs”. This will make it difficult for an interceptor to intercept the intended message. Lastly, it is worth mentioning that, although in the present example, the blue light is used to transmit the intended message and the UV light is used for security purpose, it works vice versa. Further combining encryptions (such as inserting random characters and Base64 as mentioned above), it would make the interceptors nearly impossible to intercept the intended message; and thus, this example provides a simple and efficient way to transmit data highly securely in an UWSN leveraging the present PEC-PDs.

In summary, self-powered, UV and blue wavelength distinguishable PEC-PDs in both acidic and NaCl electrolytes are achieved in this example, with responsivities reaching mA/W range in both electrolytes. Moreover, an ultrafast response time, with less than 10 ms for the 405 nm blue light, and 20-30 ms for the 302 nm UV light is achieved. This example represents a breakthrough in the development of self-powered, wavelength distinguishable PEC-PDs. As further shown in this example, such devices can enhance data transmission security in an UWSN, due to the wavelength distinguishability induced extra data encryption capability, which could make the UWSN more resilient to both passive and active attacks. Further given the self-powered nature, as well as the allowed data transmission using blue light, which is the most transmissive wavelength in the ocean environment, this example significantly advances the development of low energy and maintenance costs and secure UWSNs, especially for the ocean environment.

As can be understood, the examples described above and illustrated are intended to be exemplary only. Although the illustrated embodiments suggest that the first semiconductor material is provided in the form of an n-type doped semiconductor material and that the second semiconductor material is a p-type doped semiconductor material, it is intended that the n-type doped semiconductor material can be used as the second semiconductor material and the p-type doped semiconductor material can be used as the first semiconductor material. The depicted embodiments show that the nanowire have a tunnel junction sandwiched between two nanowire sections. However, it is intended that the nanowires can have a plurality of tunnel junctions interspersed with nanowire sections as well. In these latter embodiments, the nanowire sections can alternate between n- and p-type doped semiconductors and form a series of heterojunctions longitudinally aligned with one another. In some embodiments, other color combinations can be distinguishingly detected. For instance, any color combination from 200 nm to 2 microns can be detected using corresponding semiconductor materials. In some embodiments, the tunnel junctions can include quantum dots. The scope is indicated by the appended claims.

What is claimed is:

1. A photodetector device comprising:
a semiconductor substrate;
a plurality of nanowires extending from the semiconductor substrate, the nanowires having a first section of a first semiconductor material extending from the semiconductor substrate, a tunnel junction extending from the first section, and a second section of a second semiconductor material extending from the tunnel junction, the first semiconductor material having a first bandgap energy different from a second bandgap energy of the second semiconductor material;
an electrode longitudinally spaced apart from the second sections, and forming a gap therebetween;
an electrolyte solution within the gap and surrounding the nanowires; and
a current detector having a first terminal electrically connected to the semiconductor substrate and a second terminal electrically connected to the electrode.

2. The photodetector device of claim 1 wherein the current detector detects a first electrical current signal when first photons having a first photon energy exceeding the first bandgap energy impinge at least on the first sections, the current detector detecting a second electrical current signal when second photons having a second photon energy exceeding the second bandgap energy impinge at least on the second sections, the first electrical current signal having a first polarity different from a second polarity of the second electrical current signal.

3. The photodetector device of claim 2 further comprising a controller communicatively coupled to the current detector, the controller having a processor and a non-volatile computer memory having stored thereon instructions that when executed by the processor perform the steps of:
at least one of:
upon receiving a given electrical signal of the first polarity, generating a signal indicative that photons of the first photon energy have impinged on the nanowires, and
upon receiving a given electrical signal of the second polarity, generating a signal indicative that photons of the second photon energy have impinged on the nanowires.

4. The photodetector device of claim 1 wherein the first semiconductor material is an n-type doped semiconductor material, the second semiconductor material is a p-type doped semiconductor material.

5. The photodetector device of claim 4 wherein the n-type doped semiconductor material is an n-type doped gallium nitride (GaN), and the p-type doped semiconductor material is a p-type doped indium gallium nitride (InGaN).

6. The photodetector device of claim 1 wherein the tunnel junction has a third section of a third semiconductor material extending from the first section of the nanowire, a fourth section of a fourth semiconductor material extending from the third section, and a fifth section of a fifth semiconductor material extending between the fourth section and the second section of the nanowire.

7. The photodetector device of claim 6 wherein the third semiconductor material is an n++-type doped semiconductor material, and the fifth semiconductor material is a p++-type doped semiconductor material.

8. The photodetector device of claim 7 wherein the n++-type doped semiconductor material is an n++-type doped GaN, and the p++-type doped semiconductor material is p++-type doped GaN.

9. The photodetector device of claim 6 wherein the second semiconductor material and the fourth semiconductor material are provided in the form of a similar semiconductor material.

10. The photodetector device of claim 9 wherein the similar semiconductor material is indium gallium nitride (InGaN).

11. The photodetector device of claim 1 further comprising an enclosure enclosing the semiconductor substrate, the plurality of nanowires, the electrode and the electrolyte solution.

12. The photodetector device of claim 1 wherein the electrolyte solution has a sodium chloride (NaCl) electrolyte.

13. The photodetector device of claim 1 where the electrolyte solution includes ions selected from a group comprising: K⁺, Mg²⁺, Ca²⁺, Br, SO₄²⁻, and CO₃²⁻.

14. An underwater wireless sensor network comprising the photodetector device of claim 1.

15. A method of distinguishingly detecting photons of different bandgap energies using a photodetector device, the photodetector device having a semiconductor substrate, a plurality of nanowires extending from the semiconductor substrate, the nanowires having a first section of a first semiconductor material extending from the semiconductor substrate, and a second section of a second semiconductor material extending from the first section, the first semiconductor material having a first bandgap energy different from a second bandgap energy of the second semiconductor material, an electrode longitudinally spaced apart from the second sections, and forming a gap therebetween, and an electrolyte solution within the gap and surrounding the nanowires, the method comprising:
using tunnel junctions extending between the first sections and the second sections of the nanowires, reducing built-in electric fields occurring within the nanowires;
using a current detector having a first terminal electrically connected to the semiconductor substrate and a second terminal electrically connected to the electrode, detecting a given electrical current signal having a given polarity; and
using a controller, generating a signal indicative that photons of either a first photon energy or a second photon energy have impinged on the nanowires based on the given polarity.

16. The method of claim 15 wherein the tunnel junction has a third section of a third semiconductor material extending from the first section of the nanowire, a fourth section of a fourth semiconductor material extending from the third section, and a fifth section of a fifth semiconductor material extending between the fourth section and the second section of the nanowire.

17. The method of claim 16 wherein the third semiconductor material is an n++-type doped semiconductor material, and the fifth semiconductor material is a p++-type doped semiconductor material.

18. The method of claim 17 wherein the n++-type doped semiconductor material is an n++-type doped GaN, and the p++-type doped semiconductor material is p++-type doped GaN.
